(19) United States
(12) Patent Application Publication
(10) Pub. No.: US 2017/0365536 A1
(43) Pub. Date: Dec. 21, 2017

(54) Electronic Device

(71) Applicant: Hitachi Automotive Systems, Ltd., Hitachinaka-shi, Ibaraki (JP)

(72) Inventors: Mina AMO, Tokyo (JP); Nobutake TSUYUNO, Tokyo (JP); Takeshi TOKUYAMA, Tokyo (JP); Toshiya SATOH, Hitachinaka (JP)

(21) Appl. No.: 15/544,150

(22) PCT Filed: Jan. 8, 2016
(86) PCT No.: PCT/JP2016/050410

§ 371 Date: Jul. 17, 2017

(30) Foreign Application Priority Data
Jan. 28, 2015 (JP) 2015-013875

(51) Int. Cl. H01L 23/29; H01L 21/56; H01L 23/44; H02M 7/00; H05K 7/20; H02P 27/08; H01L 25/18; H01L 23/00; H02M 7/5395; B60L 11/18

(52) U.S. Cl. CPC H01L 23/293; H02M 7/003; H01L 21/565; H01L 23/44; H05K 7/20927; H01L 2224/73263; H01L 2224/73221; H01L 2224/48245; H01L 2224/48091; H01L 2224/40137; H01L 2224/32245; H01L 25/18; H01L 24/73; H01L 24/48; H01L 24/40; H01L 24/32; B60L 2210/40; H01L 2924/1203; H01L 2924/13055; H02M 7/5395; B60L 11/1803; H02P 27/08

(57) ABSTRACT

An electronic device includes electronic components and an epoxy resin portion which seals the electronic components. The electronic device is disposed in a refrigerant which cools the electronic components. A first layer having a three-dimensional crosslinking structure is formed on a surface or inside of the epoxy resin portion. The first layer is formed such that a length calculated by cube root of an average free volume in the three-dimensional crosslinking structure of the first layer is shorter than a length of the longest side of molecules forming the refrigerant.

### TECHNICAL FIELD

The present invention relates to an electronic device having a function to cool electronic components included therein.

### BACKGROUND ART

In recent years, offshore wind power generation effectively utilizing natural energy is focused to prevent from global warming. Wind power generation needs a semiconductor apparatus represented by a power conversion module for converting rotation of a windmill into power and a low-voltage module for such as a motor control device. A method using switching of a highly efficient power semiconductor is mainly used in a power converter, and a semiconductor device is insulation-protected by being sealed by gel and resin. The ocean atmosphere is more humid than the land atmosphere and contains much salt. Therefore, a power converter and a control device excellent in moisture proof and waterproof properties are needed.

Further, to promote energy saving and realize a low carbon society, motorization of vehicles such as electric vehicles and hybrid vehicles is rapidly developed. Especially, a role of an inverter which is a basic component of a motorization system is more diversified than before, and miniaturization and high output of the inverter are required at the same time. The inverter includes, as a main component, a power semiconductor module in which a power semiconductor chip using such as a transistor and a diode is sealed by resin. In a power semiconductor module for an electric vehicle and a hybrid vehicle, heat is generated by energization with an increase in a current capacity of a device and an increase in a current density by miniaturization. Therefore, a cooling unit is provided to prevent from a temperature rise in the power semiconductor module. As the cooling method, a refrigerant circulation method using water, oil, and organic solvent are mainly used, and a waterproof structure with respect to a refrigerant is needed.

Epoxy resin is known as resin used to cover a conductor by such as electronic components and a power cable (refer to PTL 1). PTL 1 describes that a water absorption property becomes lower, and a water resistance becomes higher than before by introducing a hydrophobic group such as an alkyl group to a branched chain of epoxy resin.

### CITATION LIST

### Patent Literature

PTL 1: JP 2004-119667 A1

### SUMMARY OF INVENTION

### Technical Problem

Epoxy resin including a hydrophobic group has poor wettability with a semiconductor device and a conductor such as a wiring and an electric wire and has poor adhesion. When such epoxy resin is used as an insulator, peeling from a conductor and a void in a molding occur by heat curing, and consequently water may accumulate, and insulation may be reduced.

An issue is to provide an electronic device capable of preventing entry of a refrigerant such as water, oil, and organic solvent without deteriorating reliability such as insulation.

### Solution to Problem

An electronic device according to the present invention includes electronic components and an epoxy resin portion which seals the electronic components. The electronic device is disposed in a refrigerant which cools the electronic components. A first layer is formed on a surface or inside of the epoxy resin portion. The first layer has the three-dimensional crosslinking structure. The first layer is formed such that a length calculated by cube root of an average free volume in the three-dimensional crosslinking structure is shorter than a length of the longest side of molecules included in the refrigerant.

### Advantageous Effects of Invention

According to the present invention, entry of a refrigerant can be prevented, and waterproof effects can be improved.

### BRIEF DESCRIPTION OF DRAWINGS

FIG. 1 is a diagram illustrating a control block of a hybrid vehicle.

FIG. 2 is a diagram describing a configuration of an electric circuit of an inverter circuit.

FIG. 3(a) is a perspective view of a semiconductor module.

FIG. 3(b) is a perspective view of the semiconductor module viewed from different viewpoint.

FIG. 3(c) is a sectional schematic view of the semiconductor module cut on line IVa-IVa.

FIG. 4 is a circuit diagram illustrating a circuit configuration of a semiconductor module.

FIG. 5 is a perspective view of a conductor plate assembly excluding a sealing resin of a semiconductor module.

FIG. 6 is a perspective view of a conductor plate assembly excluding a first conductor plate and a third conductor plate illustrated in FIG. 5.

FIG. 7 is a sectional schematic view of a semiconductor structure 302.

FIG. 8(a) is a schematic view describing formation of a three-dimensional curing structure of a first layer.

FIG. 8(b) is a schematic view describing formation of the three-dimensional curing structure of the first layer.

FIG. 8(c) is a schematic view describing formation of the three-dimensional curing structure of the first layer.

FIG. 9 is a perspective view of a semiconductor module according to a second embodiment.

FIG. 10 is a sectional schematic view of the semiconductor module according to the second embodiment.

FIG. 11 is a sectional schematic view of a semiconductor module according to a third embodiment.

### DESCRIPTION OF EMBODIMENTS

Embodiments according to the present invention will be described below with reference to drawings.

### First Embodiment

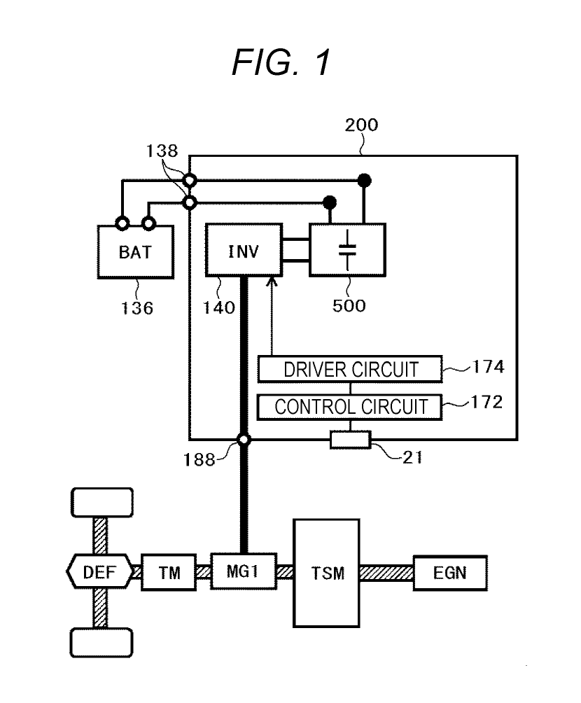

FIG. 1 is a diagram illustrating a control block of a hybrid vehicle. An engine EGN and a motor generator MG1 generate a torque for traveling of a vehicle. The motor generator MG1 generates a rotation torque and also has a function to convert mechanical energy added from the outside to the motor generator MG1 into electric power.

The motor generator MG1 is, for example, a synchronous machine or an induction machine and operates as a motor and as a power generator according to an operation method as described above. In the case where the motor generator MG1 is mounted in a vehicle, the motor generator MG1 is preferably down-sized and obtains high output, and a permanent magnet-type synchronous motor using such as a neodymium magnet is suitable. A permanent magnet-type synchronous motor is suitable for a motor for a vehicle in a viewpoint that heat generation of a rotor is lower than that of an induction motor.

An output torque of the engine EGN is transmitted to the motor generator MG1 via a power distribution mechanism TSM, a rotation torque from the power distribution mechanism TSM or a rotation torque generated by the motor generator MG1 is transmitted to a wheel via a transmission TM and a differential gear DIF. On the other hand, when regenerative breaking is operated, a rotation torque is transmitted to the motor generator MG1 from a wheel, and AC power is generated based on the supplied rotation torque. The generated AC power is converted into DC power by a power converter 200 as described below, and a high voltage battery 136 is charged, and the charged power is reused for traveling energy.

The power converter 200 will be described next. The power converter 200 converts DC power into AC power and AC power into DC power by a switching operation of a semiconductor device. An inverter circuit 140 is electrically connected to the battery 136 via a DC connector 138, and power is mutually exchanged between the battery 136 and the inverter circuit 140. In the case where the motor generator MG1 is operated as a motor, the inverter circuit 140 generates AC power based on DC power supplied from the battery 136 via the DC connector 138 and supplies the AC power to the motor generator MG1 via an AC terminal 188. A configuration including the motor generator MG1 and the inverter circuit 140 operates as an electric power generation unit.

In the embodiment, by operating the electric power generation unit by power of the battery 136 as an electric unit, a vehicle can be driven by power of the motor generator MG1. Further, in the embodiment, the battery 136 can be charged by generating power by operating the electric power generation unit as a power generation unit by power of the engine EGN or power from a wheel.

The power converter 200 includes a capacitor module 500 to smooth DC power supplied to the inverter circuit 140.

The power converter 200 includes a connector 21 for communication to receive a command from an upper control device or to send data indicating a state to the upper control device. In the power converter 200, a control circuit 172 calculates a control amount of the motor generator MG1 based on a command from the connector 21, and also the control circuit 172 calculates whether to drive as a motor or as a power generator, generates a control pulse based on a result of the calculation, and supplies the control pulse to a driver circuit 174. The driver circuit 174 generates a driving pulse for controlling the inverter circuit 140 based on the supplied control pulse.

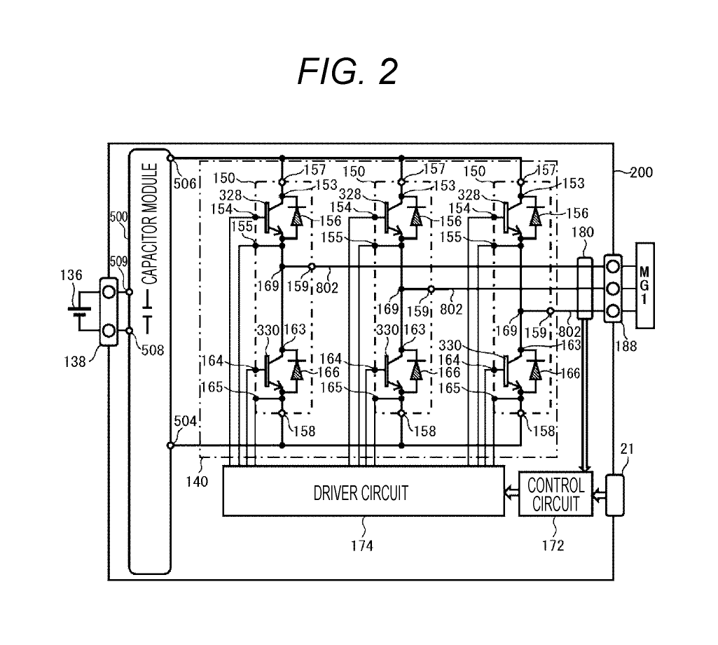

Next, a configuration of an electric circuit of the inverter circuit 140 will be described with reference to FIG. 2. In the embodiment, an insulated gate bipolar transistor is used as a semiconductor device and hereinafter called IGBT.

An IGBT 328 and a diode 156 of an upper arm and an IGBT 330 and a diode 166 of a lower arm form a series circuit 150 of the upper and lower arms. The inverter circuit 140 includes the series circuit 150 corresponding to three phases including U, V, and W phases of AC power to be output.

These three phases correspond to each phase winding of three phases of an armature winding of the motor generator MG1 in the embodiment. The series circuits 150 of upper and lower arms of each of three phases output AC current from an intermediate electrode 169 which is an intermediate portion of the series circuit. This intermediate electrode 169 is connected to an AC bus bar 802 which is an AC power line to the motor generator MG1 through AC terminals 159 and 188.

A collector electrode of the IGBT 328 of an upper arm is electrically connected to a positive electrode-side capacitor terminal 506 of the capacitor module 500 via a DC positive electrode terminal 157. An emitter electrode of the IGBT 330 of a lower arm is electrically connected to a negative electrode-side capacitor terminal 504 of the capacitor module 500 via a DC negative electrode terminal 158.

As described above, the control circuit 172 receives a control command from an upper control device via the connector 21. Based on the control command, the control circuit 172 generates a control pulse which is a control signal to control the IGBT 328 and the IGBT 330 forming an upper arm or a lower arm of the series circuit 150 of each phase forming the inverter circuit 140 and supplies the control pulse to the driver circuit 174.

Based on the above-described control pulse, the driver circuit 174 supplies a drive pulse to control the IGBT 328 and the IGBT 330 forming an upper arm or a lower arm of the series circuit 150 of each phase to the IGBT 328 and the IGBT 330 of each phase. The IGBT 328 and the IGBT 330 convert DC power supplied from the battery 136 into three-phase AC power by conducting or cutting off power based on the drive pulse from the driver circuit 174, and the converted power is supplied to the motor generator MG1.

Each of the IGBT 328 of an upper arm and the IGBT 330 of a lower arm include a collector electrode, an emitter electrode for a signal, and a gate electrode. The diode 156 of an upper arm is electrically connected between a collector electrode terminal 153 and an emitter electrode terminal 155. The diode 166 is electrically connected between a collector electrode terminal 163 and an emitter electrode terminal 165.

A metal-oxide-semiconductor field-effect transistor (hereinafter abbreviated as MOSFET) may be used as a switching power semiconductor device. In this case, the diode 156 and the diode 166 are not needed. As the switching power semiconductor device, an IGBT is suitable in the case where a DC voltage is relatively high, and a MOSFET is suitable in the case where a DC voltage is relatively low.

The capacitor module 500 includes the positive electrode-side capacitor terminal 506, the negative electrode-side capacitor terminal 504, a positive electrode-side power source terminal 509, and a negative electrode-side power source terminal 508. High-voltage DC power from the battery 136 is supplied to the positive electrode-side power source terminal 509 and the negative electrode-side power source terminal 508 via the DC connector 138 and supplied to the inverter circuit 140 from the positive electrode-side capacitor terminal 506 and the negative electrode-side capacitor terminal 504 of the capacitor module 500.

On the other hand, DC power converted by the inverter circuit 140 from AC power is supplied to the capacitor module 500 from the positive electrode-side capacitor terminal 506 and the negative electrode-side capacitor terminal 504, supplied to the battery 136 via the DC connector 138 from the positive electrode-side power source terminal 509 and the negative electrode-side power source terminal 508, and stored in the battery 136.

The control circuit 172 includes a microcomputer for calculating a switching timing of the IGBT 328 and the IGBT 330. As input information, a target torque value required for the motor generator MG1, a value of a current to be supplied from the series circuit 150 to the motor generator MG1, and a magnetic pole position of a rotor of the motor generator MG1 are input to the microcomputer.

The target torque value is based on a command signal output from an upper control device (not illustrated). A current value is detected based on a detection signal by a current sensor 180. A magnetic pole position is detected based on a detection signal output from a rotation magnetic pole sensor (not illustrated) such as a resolver provided to the motor generator MG1. In the embodiment, a case is exemplified where the current sensor 180 detects current values of three phases. However, current values for two phases may be detected, and currents for three phases may be calculated.

A microcomputer in the control circuit 172 calculates a current command value of d and q axes of the motor generator MG1 based on a target torque value. The microcomputer calculates voltage command values of the d and q axes based on a difference between the calculated current command values of the d and q axes and detected current values of the d and q axes and converts the calculated voltage command values of the d and q axes are converted into voltage command values of the U, V, and W phases based on the detected magnetic pole position. Then, the microcomputer generates pulsed modulated waves based on a comparison between a basic wave (sine wave) and a carrier wave (a triangle wave) based on the voltage command values of the U, V, and W phases and outputs the generated modulated wave to the driver circuit 174 as a pulse width modulation (PWM) signal.

In the case of driving a lower arm, the driver circuit 174 outputs a drive signal amplifying the PWM signal to a gate electrode of the IGBT 330 of a corresponding lower arm. In addition, in the case of driving an upper arm, the driver circuit 174 shifts a level of a reference potential of the PWM signal to a level of a reference potential of the upper arm, amplifies the PWM signal, and output the amplified signal to each gate electrode of the IGBT 328 of a corresponding upper arm as a drive signal.

Temperature information on the series circuit 150 is input from a temperature sensor (not illustrated) provided to the series circuit 150 to a microcomputer. Further, voltage information on a DC positive electrode side of the series circuit 150 is input to the microcomputer. The microcomputer detects an excessive voltage and an excessive voltage based on the information, and in the case where an excessive voltage or an excessive voltage is detected, switching operations of all of the IGBT 328 and the IGBT 330 are stopped.

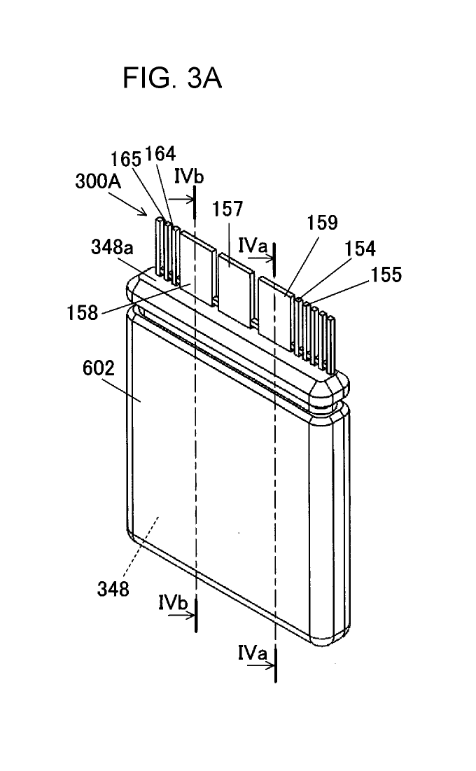

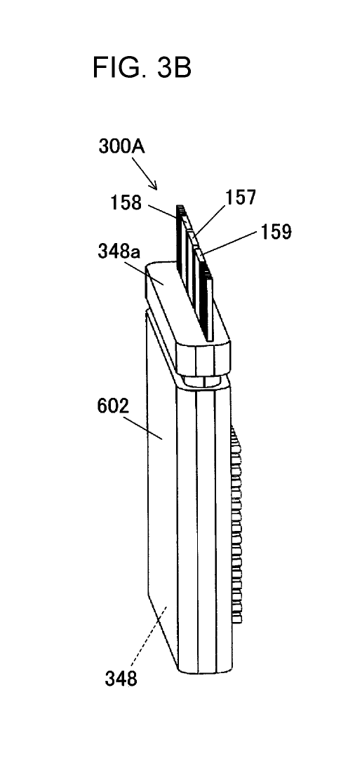

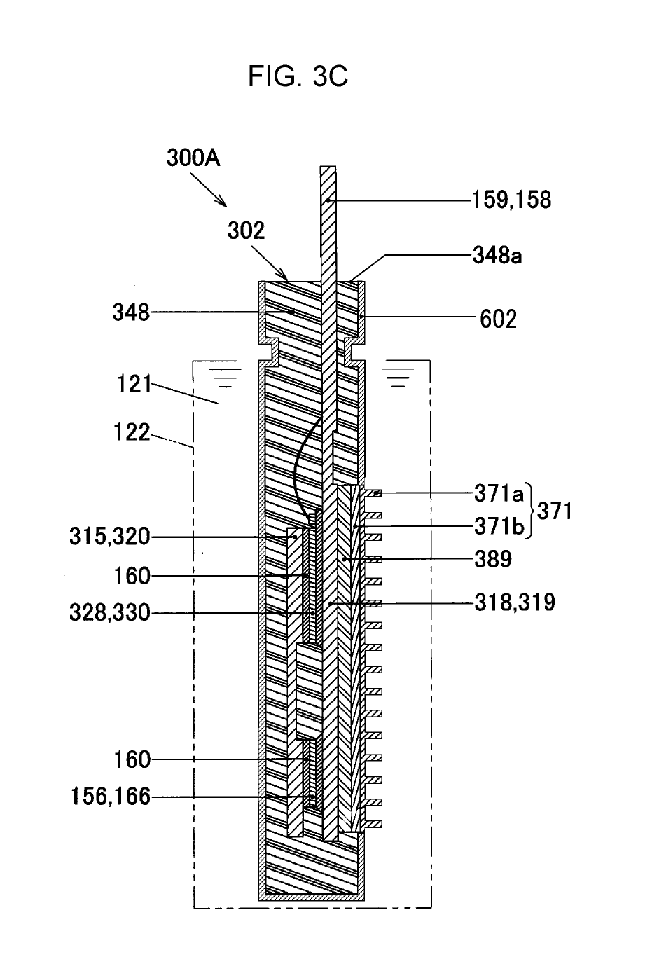

Configurations of semiconductor modules 300a to 300c to be used in the inverter circuit 140 will be described with reference to FIGS. 3 to 6. The above-described semiconductor modules 300a to 300c (refer to FIG. 2) have the same structure, and therefore a structure of the semiconductor module 300a (hereinafter called a semiconductor module 300A) will be representatively described.

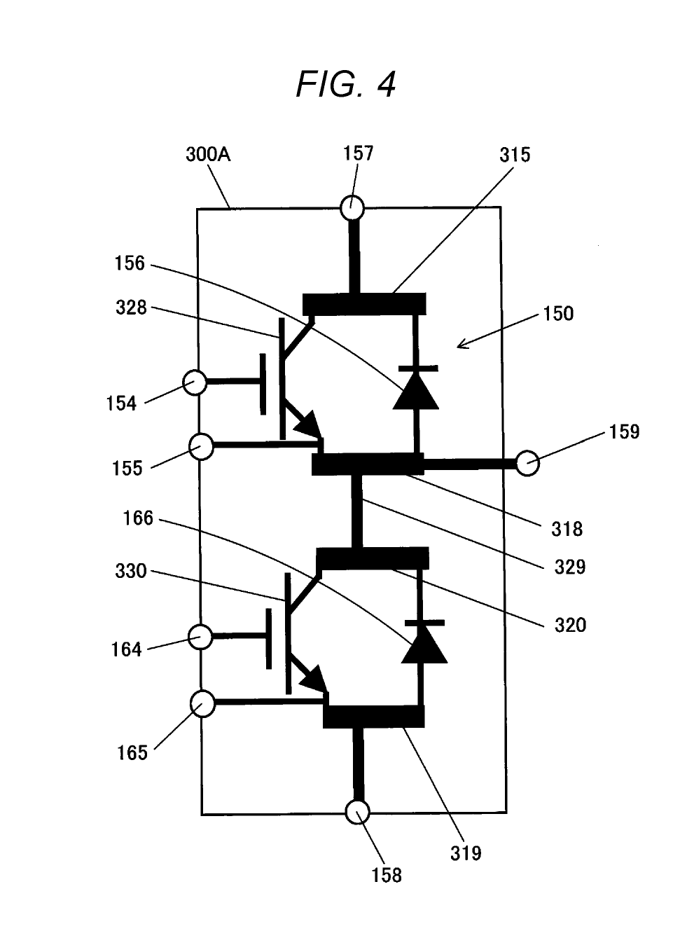

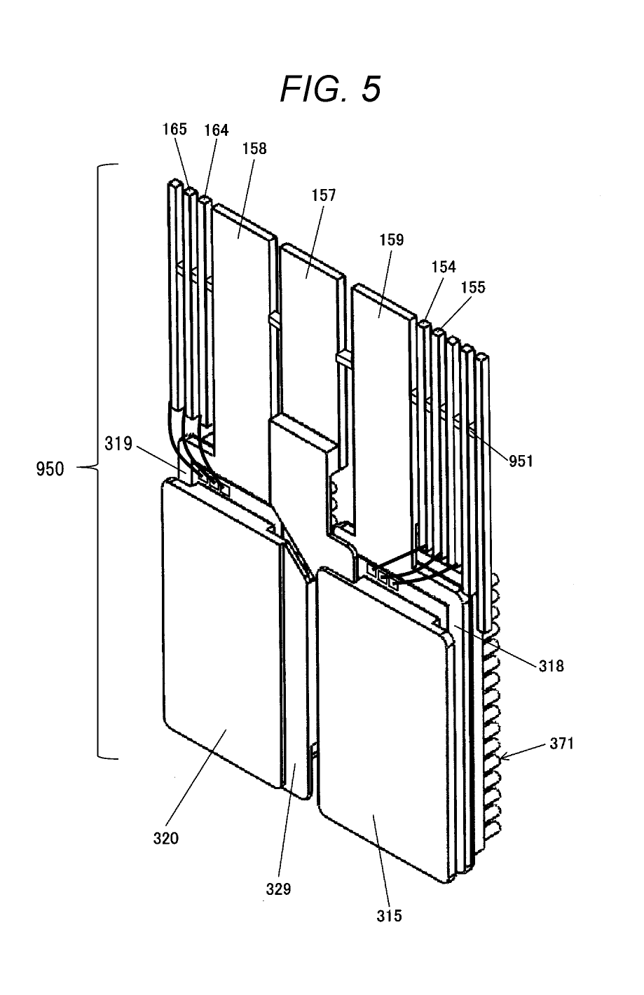

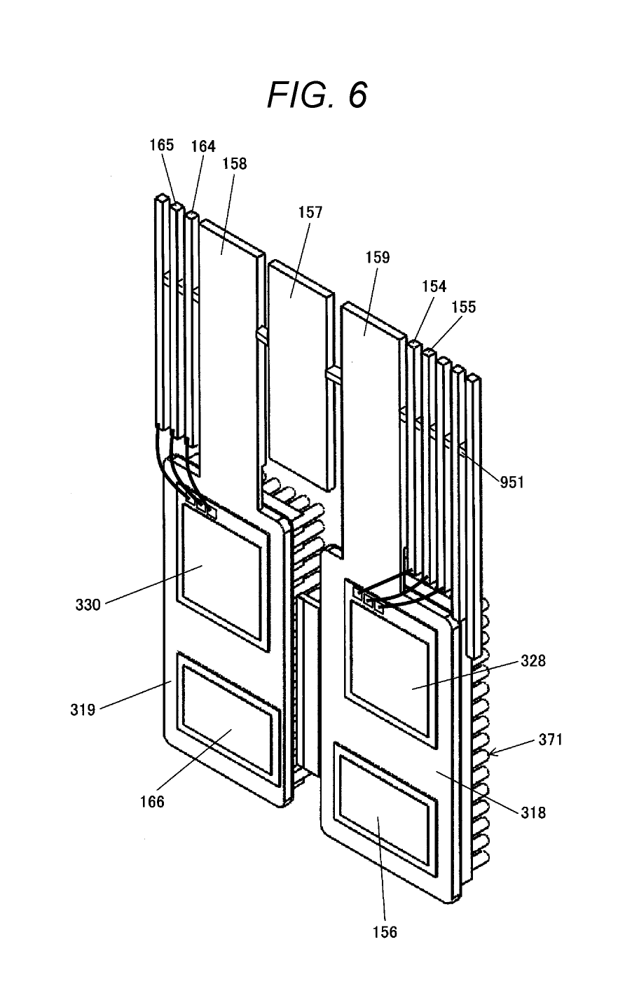

FIGS. 3(a) and 3(b) are perspective views of the semiconductor module 300A. FIG. 3(c) is a sectional schematic view of the semiconductor module 300A. FIG. 3(a) is a sectional schematic view cut on line IVa-IVa. In FIG. 3(c), component members indicated on a sectional surface cut on line IVb-IVb are also denoted by reference signs. FIG. 4 is a circuit diagram illustrating a circuit configuration of the semiconductor module 300A. FIG. 5 is a perspective view of a conductor plate assembly 950 excluding an epoxy resin 348 (sealing resin) of the semiconductor module 300A for clarification. FIG. 6 is a perspective view of the conductor plate assembly 950 excluding a first conductor plate 315 and a third conductor plate 320 illustrated in FIG. 5.

As illustrated in FIG. 3(c), the semiconductor module 300A includes power semiconductor devices (the IGBT 328, the IGBT 330, the diode 156, and the diode 166) forming the series circuit 150 illustrated in FIGS. 2 and 4. These power semiconductor devices are sealed by a sealing resin including the epoxy resin 348.

A circuit configuration of a semiconductor module will be described with reference to FIG. 4. As illustrated in FIG. 4, a collector electrode of the IGBT328 on an upper arm side and a cathode electrode of the diode 156 on the upper arm side are connected via the first conductor plate 315. Similarly, a collector electrode of the IGBT 330 on a lower arm side and a cathode electrode of the diode 166 on the lower arm side are connected via the third conductor plate 320. An emitter electrode of the IGBT 328 on the upper arm side and an anode electrode of the diode 156 on an upper arm side are connected via the second conductor plate 318. Similarly, an emitter electrode of the IGBT 330 on a lower arm side and an anode electrode of the diode 166 on the lower arm side are connected via a fourth conductor plate 319. The second conductor plate 318 and the third conductor plate 320 are connected by the intermediate electrode 329. The series circuit 150 of upper and lower arms are formed by such circuit configuration.

As illustrated in FIGS. 3(c) and 6, a power semiconductor device (the IGBT 328, the IGBT 330, the diode 156, and the diode 166) has a plate flat structure, and each electrode of the power semiconductor device is formed on front and back surfaces.

As illustrated in FIGS. 3(c) and 5, each electrode of the power semiconductor device is sandwiched by the first conductor plate 315 and the second conductor plate 318 or the third conductor plate 320 and the fourth conductor plate 319, which are disposed so as to face each electrode surface. Specifically, the first conductor plate 315 and the second conductor plate 318 are laminated so as to face in substantially parallel via the IGBT 328 and the diode 156. Similarly, the third conductor plate 320 and the fourth conductor plate 319 are laminated so as to face in substantially parallel via the IGBT 330 and the diode 166. As illustrated in FIG. 5, the third conductor plate 320 and the second conductor plate 318 are connected via the intermediate electrode 329. By this connection, an upper arm circuit and a lower arm circuit are electrically connected, and an upper/lower arm series circuit is formed.

The first conductor plate 315 on a DC side and the third conductor plate 320 on an AC side are disposed on the substantially same plane. The first conductor plate 315 is fixed to a collector electrode of the IGBT328 on an upper arm side and a cathode electrode of the diode 156 on the upper arm side. The third conductor plate 320 is fixed to a collector electrode of the IGBT 330 on a lower arm side and a cathode electrode of the diode 166 on the lower arm side. Similarly, the second conductor plate 318 on an AC side and the fourth conductor plate 319 on a DC side are disposed on the substantially same plane. The second conductor plate 318 is fixed to an emitter electrode of the IGBT 328 on an upper arm side and an anode electrode of the diode 156 on the upper arm side. The fourth conductor plate 319 is fixed to an emitter electrode of the IGBT 330 on a lower arm side and an anode electrode of the diode 166 on the lower arm side.

A DC positive electrode terminal 157 extends from the first conductor plate 315. The AC terminal 159 extends from the second conductor plate 318. A DC negative electrode terminal 158 extends from the fourth conductor plate 319.

Each of the conductor plates 315, 318, 319, and 320 according to the embodiment is a wiring for a large current circuit and includes a material having a high heat conductivity and a low electrical resistance such as pure copper or copper alloy, and the thickness is preferably equal to or greater than 0.5 mm.

As illustrated in FIG. 3(c), a power semiconductor device is bonded to each of the conductor plates 315, 318, 319, and 320 via a metal bonding material 160. The metal bonding material 160 is, for example, a low-temperature sintered bonding material including a silver sheet and fine metal particles, or a lead-free solder having a high heat conductivity and excellent in environmental properties such as a Sn—Cu solder, a Sn—Ag—Cu solder, and a Sn—Ag—Cu—Bi solder.

Gate electrode terminals 154 and 164 and the emitter electrode terminals 155 and 165 for connecting to the driver circuit 174 are connected to a gate electrode and an emitter electrode of a power semiconductor device by such as wire bonding and ribbon bonding. Aluminum and gold are preferably used for a wire and a ribbon. Instead of the wire and the ribbon, a solder may be used for bonding. Pure copper or copper alloy is preferably used in the gate electrode terminals 154 and 164 and the emitter electrode terminals 155 and 165. The DC positive electrode terminal 157, the DC negative electrode terminal 158, the AC terminal 159, the gate electrode terminals 154 and 164, the emitter electrode terminals 155 and 165, and other terminals for current detection and temperature detection are arranged in a row and integrally held by being connected by a tie bar 951 including insulating resin at predetermined intervals.

As illustrated in FIGS. 3(c) and 5, the semiconductor module 300A includes a heat dissipating fin 371. As illustrated in FIG. 3(c), the heat dissipating fin 371 includes a fin plate 371a and a reinforcement plate 371b to enhance rigidity of the fin plate 371a. The fin plate 371a includes a rectangular flat plate base and a plurality of columnar fins projected on a surface of the base. The reinforcement plate 371b is a rectangular flat plate. An outer shape of the reinforcement plate 371b is substantially same as an outer shape of the base of the fin plate 371a. The base of the fin plate 371a and the reinforcement plate 371b are positioned and bonded so as to be flush with an outer peripheral-side surface of the base of the fin plate 371a and an outer peripheral-side surface of the reinforcement plate 371b.

The semiconductor module 300A is disposed in a case 122. The heat dissipating fin 371 exchanges heat with a refrigerant 121 in the case 122, and heat generated in the semiconductor module is radiated into the refrigerant 121. The refrigerant 121 flows in a direction orthogonal to a projecting direction of each fin from the base and circulates in the case 122 by a circulator (not illustrated).

An insulating plate 389 having insulation properties is bonded on outer side surfaces of the second conductor plate 318 and the fourth conductor plate 319 (surface on an opposite side of a bonding surface of a semiconductor device), and the reinforcement plate 371b is bonded on an outer side surface of the insulating plate 389. After transfer molding to be described later, the fin plate 371a is bonded on an exposed surface of the reinforcement plate 371b. Specifically, a surface of the fin plate 371a on which a fin is formed is exposed from the epoxy resin 348 which is a sealing member. The insulating plate 389 includes an inorganic compound such as insulating ceramic and an organic compound such as insulating resin. The insulating plate 389 is disposed between the heat dissipating fin 371 and the conductor plates 318 and 319 and insulates both of them. A material having a high heat conductivity is preferably selected for a material of the insulating plate 389. In the case where the insulating plate 389 is formed of resin, the insulating plate 389 is preferably connected to the conductor plates 318 and 319 and the reinforcement plate 371b in a state before resin components are completely cured, specifically in an adhesive state. In the case where the reinforcement plate 371b and the fin plate 371a forming the heat dissipating fin 371 are formed of an insulating material, the insulating plate 389 can be omitted.

The reinforcement plate 371b and the fin plate 371a are made of a metal material having a higher heat conductivity than the epoxy resin 348 used in a sealing resin, such as aluminum, copper, and magnesium, and a ceramic material such as alumina. A material having higher rigidity than a material of the fin plate 371a is preferably selected for a material of the reinforcement plate 371b. In the embodiment, different materials are selected for the reinforcement plate 371b and the fin plate 371a.

The second conductor plate 318 or the fourth conductor plate 319, the insulating plate 389, the reinforcement plate 371b, and the fin plate 371a are boned by a method such as welding, soldering, and friction stir welding (FSW). If the strength of the fin plate 371a is sufficient, the reinforcement plate 371b can be omitted.

The second conductor plate 318 and the fourth conductor plate 319 are bonded to the heat dissipating fin 371 via an insulating plate 389 in a heat conductive manner. Heat generated in the semiconductor devices 156, 166, 328, and 330 is transferred to the second conductor plate 318 or the fourth conductor plate 319, transferred to the heat dissipating fin 371 via the insulating plate 389, and radiated into the refrigerant 121 from the heat dissipating fin 371.

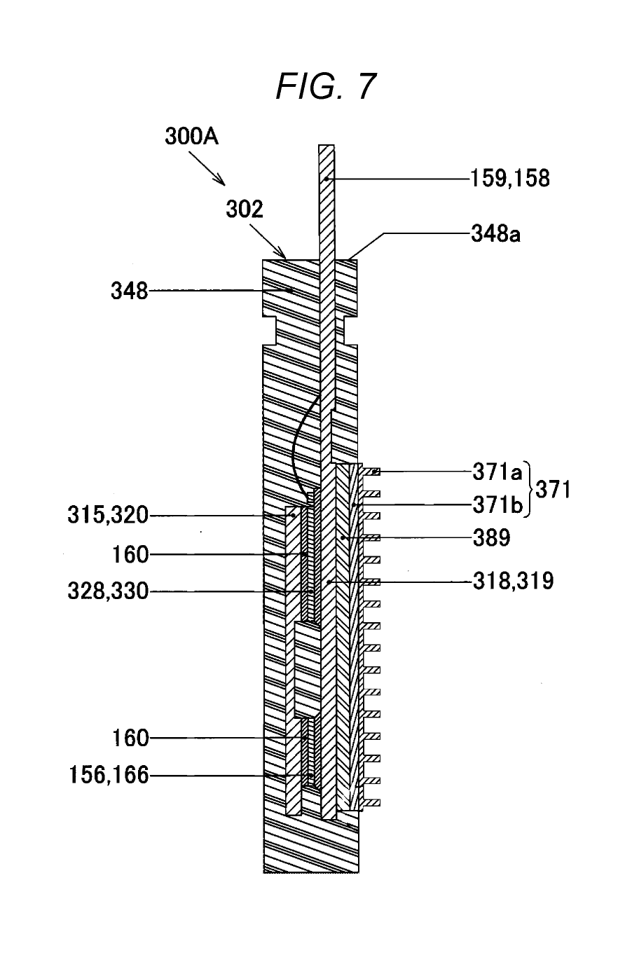

A manufacturing method for the semiconductor module 300A according to the first embodiment will be described. First, the semiconductor structure 302 is formed by molding the conductor plate assembly 950 illustrated in FIG. 5 by using the insulating epoxy resin 348 by such as a transfer molding method. In the transfer molding method, the conductor plate assembly 950 is fixed in a preliminary heated mold, and molding is performed by injecting pressure in a mold while melting curable resin such as epoxy resin. Consequently, the conductor plate assembly 950 including a power semiconductor device is sealed by a sealing resin, and the semiconductor structure (module sealing body) 302 illustrated in FIG. 7 is formed. When transfer molding is performed, an outer side surface (a surface opposite to a bonding surface with the insulating plate 389) of the reinforcement plate 371b is exposed by the sealing resin 348. As illustrated FIGS. 3 and 3(c), the sealing resin 348 includes a terminal surface 348a disposed in a state in which terminals 157, 158, 159, 154, 155, 164, and 165 are mutually insulated.

Subsequently, after the semiconductor structure 302 is set in a reaction tube, a surface of an epoxy resin portion is directly fluorinated in a fluorine gas atmosphere, and a first layer 602 in which a substitution ratio is 0.8 is formed approximately five μm (refer to FIG. 3(c)). In the embodiment, the first layer 602 is formed on an outer surface of the semiconductor structure 302. A region formed on the first layer 602 is a region including the whole of a contact region of the refrigerant 121 in the semiconductor structure 302. Herein, the substitution ratio means C—F coupling/(C—H coupling+C—F coupling) in the main chain structure.

The semiconductor module 300A manufactured in this manner is excellent in adhesion with internal electronic components sealing such as a conductor plate since epoxy resin is not fluorinated during molding. Further, 80% of hydrogen bonded to carbon of the first layer 602 is substituted with fluorine, and an average free volume in a three-dimensional crosslinking structure is sealed with fluorine to prevent entry of a refrigerant.

On the other hand, when the conductor plate assembly 950 is molded, if a hydrophobic group is introduced into a sealing resin, the sealing resin is easily repelled and has poor wettability and poor adhesion with internal electronic components to seal a diode, an IGBT, and a conductor plate. When such a sealing resin is used as an insulator, peeling from such as a conductor and a void in a sealing molding body are occurred when heat curing is performed. Consequently, water may accumulate, and insulation may be reduced.

In the present invention, epoxy resin used in an integrated molding is not especially limited as long as a curable resin component capable of sealing molding is used. However, epoxy resin components are preferably used in which an epoxy resin, a curing agent, a curing accelerator, and an inorganic filler are essential components.

In the embodiment, a fluorine atom is selected such that a length calculated by cube root of an average free volume in the three-dimensional crosslinking structure of the first layer 602 is shorter than a length of the longest side of molecules forming the refrigerant. However, it is not limited as long as the fluorine atom can be substituted. To prevent entry of a refrigerant, elements having water repellency when being substituted is further preferable. For example, halogen elements such as fluorine, bromine, chlorine, and iodine are used.

A glass transition temperature of resin having the three-dimensional crosslinking structure of the first layer 602 is preferably equal to or greater than 50° C. Although it depends on an application temperature range of an electronic device, when the three-dimensional crosslinking structure becomes movable (a rubber state) by heat at the glass transition temperature or higher. Therefore, even if an average free volume is sealed by elements such as fluorine, entry of a refrigerant may not be prevented. Ina semiconductor apparatus represented by such as a high pressure module for such as an inverter for a hybrid vehicle, a glass transition temperature of resin having a three-dimensional crosslinking structure of the first layer 602 is preferably equal to or greater than 130° C.

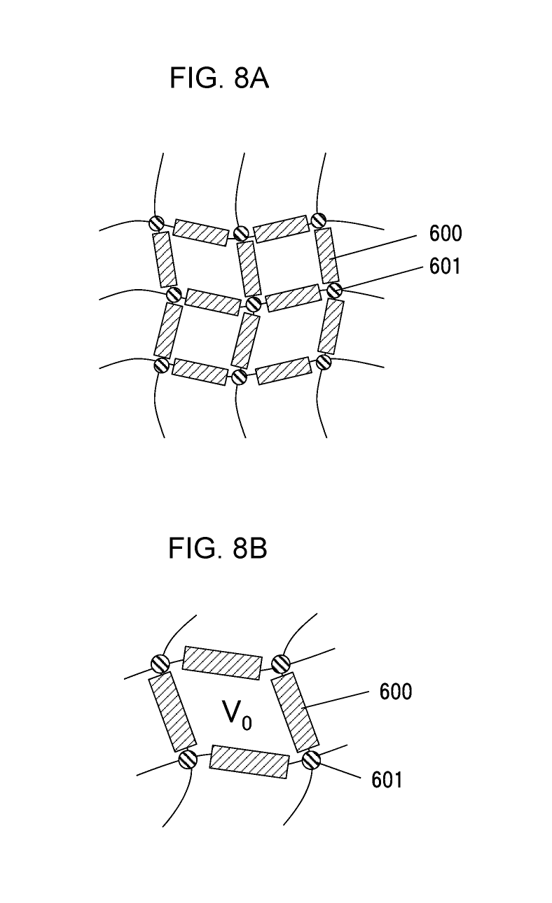

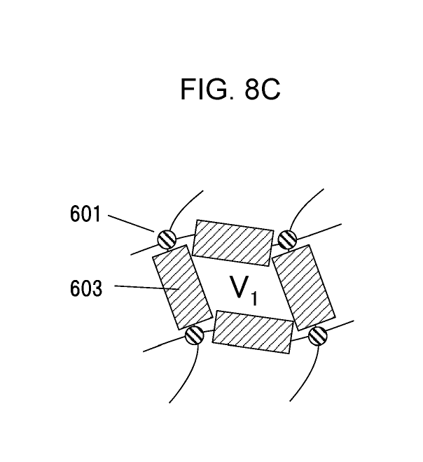

A three-dimensional curing structure of a first layer will be described with reference to FIGS. 8(a) to 8(c). FIG. 8(a) indicates a model of the three-dimensional crosslinking structure. As illustrated in FIG. 8(a), in a three-dimensional curable resin, a main chain 600 of resin is joined at a crosslinking point 601. In fact, although the curable resin has three-dimensional network structure like a mesh, for clarification, one curable resin is exemplified in FIGS. 8(b) and 8(c), and fluorine processing is described as an example. FIG. 8(b) is a schematic view of a three-dimensional curable resin before the fluorine processing. A structure of the main chain 600 of resin includes hydrogen bonded to carbon which is a main chain skeleton. A gap in a mesh structure surrounded by the main chain 600 of resin and the crosslinking point 601 is an average free volume V0 before the fluorine processing. FIG. 8(c) is a schematic view of the three-dimensional curable resin after the fluorine processing. In a structure of the main chain 600 of resin, hydrogen bonded to carbon which is a main chain skeleton is substituted with fluorine which is a larger element than hydrogen. Consequently, an average free volume V0 becomes V1, and the average free volume V1 after processing becomes smaller than the average free volume V0 before processing.

That is, a gap opened before the processing is sealed by fluorine. As a substitution ratio is increased, an average free volume is decreased. Therefore, it is effective to increase a level of the substitution ratio to prevent entry of a refrigerant. In addition, even if an average free volume of the first layer 602 is not completely sealed by an element such as halogen, a waterproof property can be improved if a length calculated by cube root of the average free volume in a three-dimensional crosslinking structure is not shorter than a length of the longest side of molecules forming the refrigerant. This is because, even if a refrigerant enters, when the calculated length is shorter than a length of the longest side of molecules forming the refrigerant, a freedom degree is decreased, and a pressure required for entry of the refrigerant generates, and the refrigerant cannot enter into a sealed conductor.

The semiconductor module 300A according to the above-described first embodiment includes the semiconductor structure 302 and the first layer 602. The semiconductor structure 302 includes semiconductor devices 328, 330, 156, and 166, the conductor plates 318 and 319, the heat dissipating fin 371, and the epoxy resin 348. A semiconductor device is bonded to the conductor plates 318 and 319. The heat dissipating fin 371 is fixed to the semiconductor device via the conductor plates 318 and 319 and the insulating plate 389 in a heat conductive manner. The epoxy resin 348 seals the semiconductor device by exposing one surface of the heat dissipating fin 371. The first layer 602 at least covers a boundary with the epoxy resin 348 in a contact region of the refrigerant 121.

The first layer 602 having a three-dimensional crosslinking structure is sealed by elements of the first layer 602 such that a length calculated by cube root of an average free volume in the three-dimensional crosslinking structure is shorter than a length of the longest side of molecules forming the refrigerant.

By forming the first layer 602, it is prevented that the refrigerant 121 enters into the sealing resin 348. Therefore, a life of the semiconductor module 300A can be extended. Even if entry of the refrigerant cannot be completely prevented, and the refrigerant enters, if the calculated length is shorter than a length of the longest side of molecules forming the refrigerant, a freedom degree is decreased, and a pressure required for entry of the refrigerant generates, and a waterproof property is improved.

### Second Embodiment

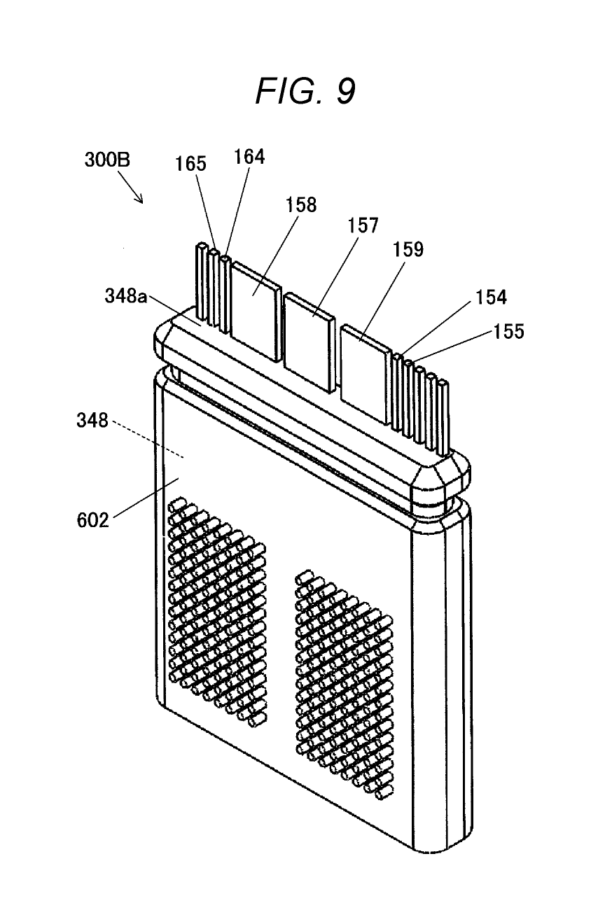

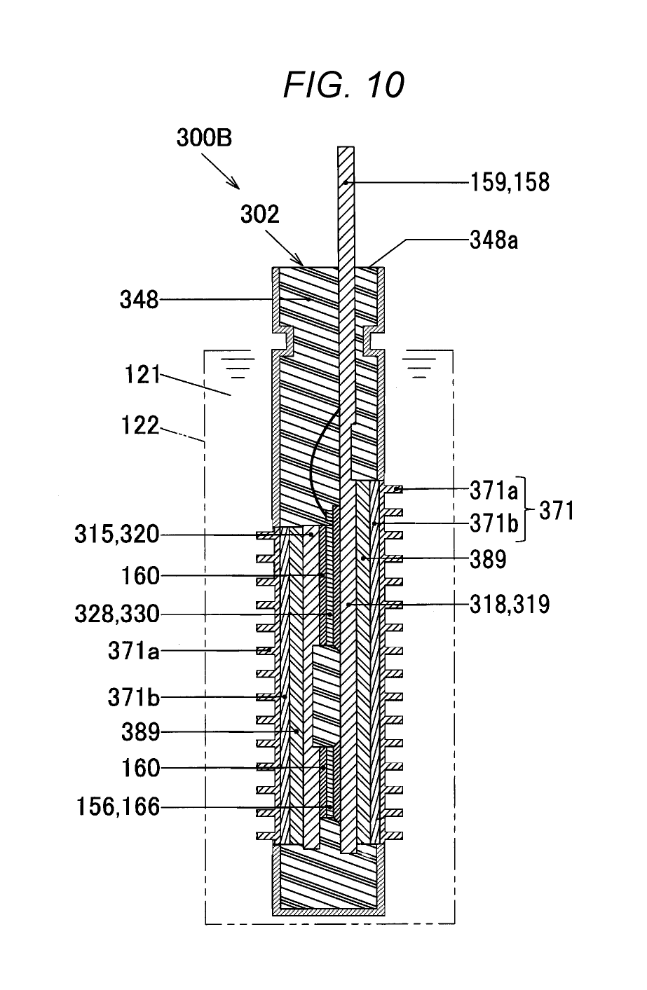

A semiconductor module 300B according to a second embodiment will be described with reference to FIGS. 9 and 10. FIG. 9 is a view similar to FIG. 3(a) and a perspective view of the semiconductor module 300B according to the second embodiment. FIG. 10 is a view similar to FIG. 3(c) and a sectional schematic view of the semiconductor module 300B according to the second embodiment. In the drawings, components same as or corresponding to those in the first embodiment are denoted by the same reference sign, and a description thereof is omitted. A point difference from the first embodiment will be described in detail below.

In the first embodiment, an example has been described in which the heat dissipating fin 371 is provided on a surface on one side of the semiconductor module 300A. In the second embodiment, the heat dissipating fins 371 are provided on both surfaces of the semiconductor module 300B.

As illustrated in FIG. 10, an insulating plate 389 is bonded on an outer side surface of a first conductor plate 315 and a third conductor plate 320. A reinforcement plate 371b is bonded on an outer surface of the insulating plate 389. After transfer molding, a fin plate 371a is bonded on an exposed surface of the reinforcement plate 371b. The insulating plate 389 includes inorganic compounds such as insulating ceramic and organic compounds such as insulating resin, and the insulating plate 389 is disposed between the heat dissipating fin 371 and the conductor plates 315 and 320 and insulates both of them. A material having a high heat conductivity is preferably selected for a material of the insulating plate 389. In the case where the insulating plate 389 is formed of resin, the insulating plate 389 is preferably connected to the conductor plates 315 320 and the reinforcement plate 371b in a state before resin component is completely cured, in other words, in an adhesive state. In the case where the reinforcement plate 371b and the fin plate 371a forming the heat dissipating fin 371 are formed of an insulating material, the insulating plate 389 can be omitted.

The reinforcement plate 371b and the fin plate 371a are made of a metal material, which has a higher heat conductivity than a material used in the sealing resin 348, such as aluminum, copper, and magnesium, and a ceramic material such as alumina. A material having higher rigidity than a material of the fin plate 371a is preferably selected for a material of the reinforcement plate 371b.

The first conductor plate 315 or the third conductor plate 320 and the insulating plate 389, the reinforcement plate 371b, and the fin plate 371a are boned by a method such as welding, soldering, and FSW. If the strength of the fin plate 371a is sufficient, the reinforcement plate 371b can be omitted.

According to such the second embodiment, operation effects similar to the effects in the first embodiment are obtained. In comparison with the first embodiment, a heat radiation area of the heat dissipating fin 371 is increased, and therefore, cooling performance can be improved in comparison with the first embodiment.

### Third Embodiment

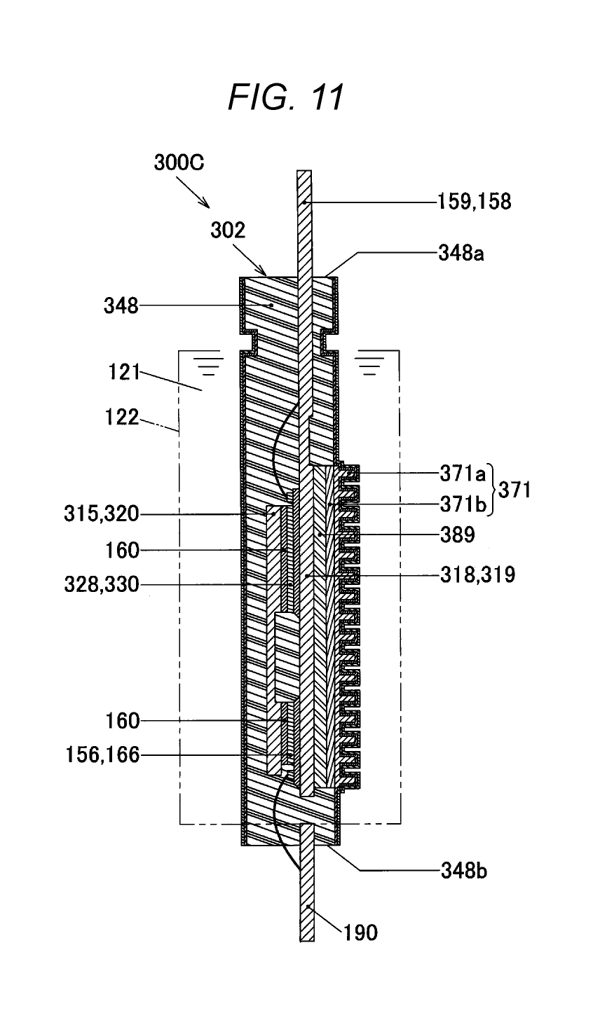

A semiconductor module 300C according to a third embodiment will be described with reference to FIG. 11. FIG. 11 is a view similar to FIG. 3(c) and a sectional schematic view of the semiconductor module 300C according to the third embodiment. In the drawings, components same as or corresponding to those in the first embodiment are denoted by the same reference sign, and a description thereof is omitted. A point difference from the first embodiment will be described in detail below.

In the first embodiment, each terminal is disposed on one terminal surface 348a. However, in the third embodiment, a terminal is disposed on a surface opposite to the terminal surface 348a (hereinafter called another terminal surface 348b). In the third embodiment, a DC negative electrode terminal 158, a DC positive electrode terminal 157, and an AC terminal 159, gate electrode terminals 154 and 164, and emitter electrode terminals 155 and 165, which are illustrated in FIG. 4 extends from the terminal surface 348a, and a current detecting terminal 190 extends from another terminal surface 348b.

In the third embodiment, as illustrated in FIG. 11, two terminal surfaces 348a and 348b are exposed. Specifically, the first layer 602 is not formed on two terminal surfaces 348a and 348b. Therefore, in comparison with the first embodiment, an area on which the first layer 602 is not formed increases. In the third embodiment, terminals and two terminal surfaces 348a and 348b are covered by a curing member, the first layer 602 is formed by coating solution, and the curing member is removed.

According to such the third embodiment, operation effects similar to the effects in the first embodiment can be obtained. In comparison with the first embodiment, an area in which the first layer 602 is formed is decreased, and therefore costs and a weight can be reduced.

A deformation to be described below is within a range of the present invention, and one or a plurality of the variations can be combined with the above-described embodiments.

First Variation

It has been exemplified in the above-described embodiments that the first layer 602 is formed by directly fluorinating an epoxy resin which is a sealing member. However, the present invention is not limited thereto. The first layer 602 can be formed by direct fluorine processing after various types of curable resin such as polyimide, polyimidazole, phenol resin, melamine resin, and epoxy resin having a different structure from a structure used in the sealing member are formed instead of the epoxy resin which is a sealing member. A region excellent in chemical resistance with respect to a refrigerant and heat resistance is preferably selected for a region in which the first layer 602 is formed while considering that the region includes the whole of a contact region of the refrigerant 121 in the semiconductor structure 302.

For example, 20 weight % polyimide dimethylformamide solution is prepared, and then a surface of the semiconductor structure 302 is coated by using this coating solution. Polyimide of the first layer 602 is formed by performing heat curing for 1 hour at 100° C. and 150° C. Further, by direct fluorine processing, a part of hydrogen bonded to carbon of the first layer is substituted with fluorine such that a length calculated by cube root of an average free volume in a three-dimensional crosslinking structure is shorter than a length of the longest side of molecules forming the refrigerant.

It has been exemplified that the first layer 602 is formed by a dipping method to dip in the coating solution. However, the present invention is not limited thereto. A method for coating the coating solution is not limited to the dipping method. The first layer 602 may be formed by coating a coating solution on the semiconductor structure 302 by using a spray and a brush. Dipping, spraying, and brushing, ora combination thereof can be used. In the case where embedding is insufficient, it is improved by recoating.

Second Variation It has been exemplified in the above-described embodiments that the first layer 602 is formed in a region including the whole of a contact region of the refrigerant 121 in the semiconductor structure 302. However, the present invention is not limited thereto. The first layer 602 may be formed in an epoxy resin portion, not on a surface of the epoxy resin portion sealing such as a conductor.

Third Variation

It has been exemplified in the above-described embodiments that the first layer 602 is formed by directly fluorinating an epoxy resin which is a sealing member by using fluorine gas. However, the present invention is not limited thereto. The first layer 602 may be formed by surface fluorine processing by a radical reaction. For example, after a solution having a fluoride radical reaction is adjusted to a constant concentration, the semiconductor structure 302 is dipped in this coating solution for coating. Then, by heating the semiconductor structure 302 at 100° C. for three hours, a part of a main chain skeleton is fluorinated.

Fourth Variation

It has been exemplified in the above-described embodiments that the first layer 602 is formed in the whole of a contact region of the refrigerant 121 in the sealing resin 348. However, the present invention is not limited thereto. The first layer 602 may be provided at least so as to cover a boundary between the sealing resin 348 and the heat dissipating fin 371. Consequently, by coating the boundary between different-type members, it is prevented that a refrigerant enters from the boundary between different-type members, and a waterproof property is improved.

Fifth Variation

It has been exemplified in the above-described embodiments that the first layer 602 is formed in the whole of a contact region of the refrigerant 121 in the sealing resin 348. However, the present invention is not limited thereto. The first layer 602 may be provided in the whole of a region contacting to the refrigerant 121 in the sealing resin 348 and the heat dissipating fin 371. Consequently, by forming the first layer 602 in the heat dissipating fin 371 in addition to the sealing resin 348, a pinhole and a flaw of a fin portion are covered, a waterproof property is improved, and long reliability can be secured. However, it is necessary to select a coating type and a film thickness of the first layer 602 while considering a heat dissipation property of the heat dissipating fin 371.

Sixth Variation

It has been exemplified in the above-described embodiments that, by directly fluorinating the first layer 602, a part of hydrogen bonded to carbon of the first layer is substituted with fluorine such that a length calculated by cube root of an average free volume in a three-dimensional crosslinking structure is shorter than a length of the longest side of molecules forming the refrigerant. However, the present invention is not limited thereto. Hydrogen may be substituted with bromide and chlorine instead of fluorine.

Seventh Variation

A power converter (inverter) has been exemplified as an electronic control device in the above-described embodiments. However, the present invention is not limited thereto. The present invention can be applied to various types of electronic control devices including electronic components.

As long as characteristics of the present invention are not impaired, the present invention is not limited to the above-described embodiments. Other embodiments envisaged within the scope of technical ideas of the preset invention are included in the scope of the present invention.

### REFERENCE SIGNS LIST

21 connector
121 refrigerant
122 case
136 battery
138 DC connector
140 inverter circuit
150 series circuit
153 collector electrode terminal
154 gate electrode terminal
155 emitter electrode terminal
156 diode
157 DC positive electrode terminal
158 DC negative electrode terminal
159 AC terminal
160 metal bonding material
163 collector electrode terminal
164 gate electrode terminal
165 emitter electrode terminal
166 diode
169 intermediate electrode
172 control circuit
174 driver circuit
180 current sensor
188 AC terminal
190 current detecting terminal
200 power converter
300A, 300B, 300C, 300D semiconductor module
302 semiconductor structure
315 first conductor plate
318 second conductor plate
319 fourth conductor plate
320 third conductor plate
328 IGBT
329 intermediate electrode
330 IGBT
348 epoxy resin
348a, 348b terminal surface
371 heat dissipating fin
371a fin plate
371b reinforcement plate
389 insulating plate
500 capacitor module
504 capacitor terminal
506 capacitor terminal
508 power source terminal
509 power source terminal
600 main chain of resin
601 crosslinking point
602 first layer
603 main chain of resin substituted with halogen
802 AC bus bar
950 conductor plate assembly
951 tie bar

1. An electronic device comprising:
electronic components; and
an epoxy resin portion configured to seal the electronic components,
the electronic device being disposed in a refrigerant to cool the electronic components,
wherein a first layer having a three-dimensional crosslinking structure is formed on a surface or inside of the epoxy resin portion, and
the first layer is formed such that a length calculated by cube root of an average free volume in the three-dimensional crosslinking structure of the first layer is shorter than a length of the longest side of molecules forming the refrigerant.

2. The electronic device according to claim 1, wherein at least a part of elements bonded with carbon elements of the first layer is elements different from hydrogen elements.

3. The electronic device according to claim 2, wherein at least a part of elements bonded with carbon elements of the first layer is halogen elements.

4. The electronic device according to claim 2, wherein at least a part of hydrogen elements bonded with carbon elements of the first layer is substituted with elements different from hydrogen elements, and a substitution ratio of the first layer is equal to or higher than 0.8.

5. The electronic device according to claim 1, wherein a glass transition temperature of the first layer is equal to or higher than 50° C.

6. The electronic device according to claim 1, comprising a heat dissipating portion including a metal material or a ceramic material,
wherein the epoxy resin portion seals the heat dissipating portion such that a part of the heat dissipating portion is exposed from the epoxy resin portion.

7. A manufacturing method for an electronic device comprising electronic components and being disposed in a refrigerant which cools the electronic components,
the manufacturing method comprising:
a first process to seal the electronic components by an epoxy resin portion; and
a second process to form a first layer having a three-dimensional crosslinking structure on a surface or inside of the epoxy resin,
wherein, in the second process, the first layer is formed such that a length calculated by cube root of an average free volume in the three-dimensional crosslinking structure of the first layer is shorter than a length of the longest side of molecules forming the refrigerant.

8. The manufacturing method for the electronic device according to claim 7, wherein, in the second process, a surface of the epoxy resin is substituted with halogen elements.

9. The manufacturing method for the electronic device according to claim 8, wherein, in the second process, a surface of the epoxy resin is substituted with fluorine elements.

10. The manufacturing method for the electronic device according to claim 9, wherein, in the second process, a surface of the epoxy resin is fluorinated in a fluorine gas atmosphere.
